(19) United States
(12) Patent Application Publication
(10) Pub. No.: US 2025/0175144 A1
(43) Pub. Date: May 29, 2025

(54) Elastic wave device and module including the same

(71) Applicant: Sanan Japan Technology Corporation, Tokyo (JP)

(72) Inventors: Yuki Koto, Tokyo (JP); Shinichi SHIOI, Tokyo (JP)

(21) Appl. No.: 18/963,427

(22) Filed: Nov. 27, 2024

(30) Foreign Application Priority Data
Nov. 29, 2023 (JP) 2023-202286

(51) Int. Cl. H03H 9/13; H03H 9/05; H03H 9/17; H03H 9/54; H03H 9/56

(52) U.S. Cl. CPC H03H 9/133; H03H 9/05; H03H 9/17; H03H 9/542; H03H 9/568

(57) ABSTRACT

An elastic wave device includes a packaging substrate with a ground electrode; a piezoelectric substrate mounted on the packaging substrate; a plurality of series resonators and a plurality of parallel resonators formed on said piezoelectric substrate to constitute a bandpass filter; an antenna pad and a node pad formed on the piezoelectric substrate; a first inductor formed on the piezoelectric substrate and connected to a first parallel resonator which is one of said plurality of parallel resonators; a second inductor connected between said node pad and said ground electrode; a capacitor formed on the piezoelectric substrate and connected in parallel between said first inductor and said 10 second inductor; Wherein said capacitor is directly connected to the antenna pad.

### CROSS-REFERENCE TO RELATED APPLICATION

The present disclosure claims priority to Japanese Patent Application No. 2023-202286 filed Nov. 29, 2023, the contents of which are herein incorporated by reference in its entirety.

### FIELD

This application relates to an elastic wave device and a module including the elastic wave device.

### BACKGROUND

With recent technological advancements, mobile terminals, exemplified by smartphones, have become increasingly miniaturized and lightweight. Elastic wave devices used in such mobile communication terminals are typically compact. Additionally, the rapid increase in communication systems that transmit and receive simultaneously has led to a surge in demand for duplexers.

With the evolution of mobile communication systems, the specification requirements for elastic wave devices have become more stringent, demanding higher performance than before.

On the low-frequency side of the passband, increasing the ground inductance value can improve the attenuation characteristics in frequency bands distant from the passband. However, the attenuation characteristics of frequency bands close to the passband may deteriorate.

On the high-frequency side of the passband, for instance, in order to increase the attenuation of higher harmonics, Patent Document 1 (JP2014-017537A) discloses a method using a capacitor to enhance the attenuation characteristics and avoid enlarging the inductor. However, the elastic wave device described in Patent Document 1 does not sufficiently improve the attenuation characteristics on both the low-frequency and high-frequency sides of the pass-band.

### SUMMARY

Some examples described herein may address the above-described problems. Some examples described herein may have an object to provide an acoustic wave device capable of improve attenuation characteristics on both the low-frequency and high-frequency sides of the passband, and a module including the acoustic wave device.

In some examples, an elastic wave device comprises:
a packaging substrate with a ground electrode;
a piezoelectric substrate mounted on the packaging substrate;
a plurality of series resonators and a plurality of parallel resonators formed on said piezoelectric substrate to constitute a bandpass filter;
an antenna pad and a node pad formed on the piezoelectric substrate;
a first inductor formed on the piezoelectric substrate and connected to a first parallel resonator which is one of said plurality of parallel resonators;
a second inductor connected between said node pad and said ground electrode;
a capacitor formed on the piezoelectric substrate and connected in parallel between said first inductor and said second inductor;
Wherein said capacitor is directly connected to the antenna pad.

In some examples, a module include above mentioned elastic wave device.

The details of one or more embodiments of the present application are set

forth in the accompanying drawings and the description below. Other features, objects, and advantages of the present application will be apparent from the description and drawings, and from the claims.

### BRIEF DESCRIPTION OF THE DRAWINGS

The accompanying drawings are intended to provide a further understanding of the present application, constitute part of this application, and illustrate exemplary embodiments of this application. The description and drawings do not limit the scope of the application.

FIG. 1 is a cross-sectional view of the elastic wave device in Embodiment 1.

FIG. 2 is a diagram illustrating a first example of an acoustic wave element (Resonator) of the acoustic wave device in Embodiment 1.

FIG. 3 is a view of a device chip viewed from below after a packaging

substrate is removed in the acoustic wave device in Embodiment 1.

FIG. 4 is a schematic circuit diagram of the elastic wave device in Embodiment 1.

FIG. 5 is a diagram showing the attenuation characteristics on the low-frequency side of the passband of the receiving filter of the elastic wave device in Embodiment 1.

FIG. 6 is a configuration of Comparative Example 3.

FIG. 7 is a characteristic diagram comparing the receiving filter of the elastic wave device in Embodiment 1 with the receiving filter of Comparative Example 3.

FIG. 8 is a longitudinal sectional view showing the application of the elastic wave device in Embodiment 1 to a module.

### DETAILED DESCRIPTION

The embodiments will be described with reference to the accompanying drawings. In the drawings, the same or corresponding parts are denoted by the same reference numerals. Duplicate descriptions of such portions may be simplified or omitted.

### Embodiment 1

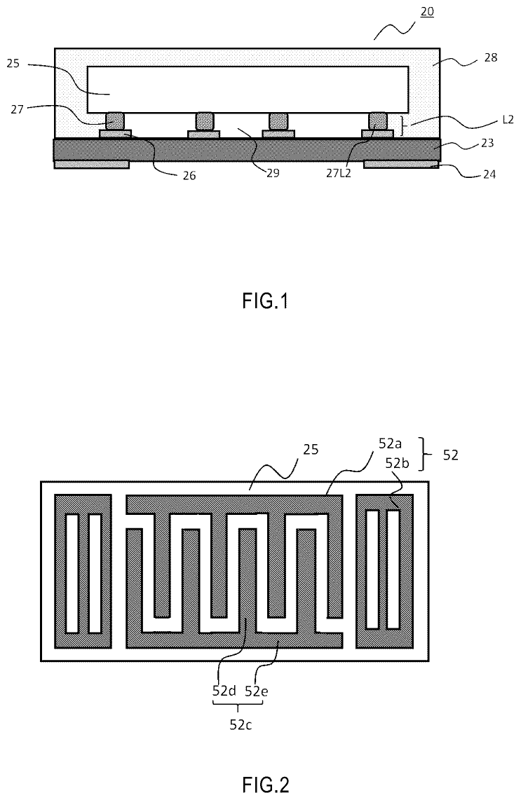

FIG. 1 illustrates a cross-sectional view of the elastic wave device in Embodiment 1.

As shown in FIG. 1, the elastic wave device 20 includes a packaging substrate 23, multiple external connection terminals 24, a device chip 25, multiple electrode pads 26, multipl bumps 27, and a sealing portion 28.

The packaging substrate 23 is a multilayer substrate made of resin. For example, the packaging substrate 23 may be a low-temperature co-fired ceramics (LTCC) multilayer substrate composed of multiple dielectric layers.

Multiple external connection terminals 24 are formed on a lower surface of the packaging substrate 23.

Multiple electrode pads 26 are formed on an upper surface of the packaging substrate 23. The electrode pads 26 may be made of copper or a copper alloy. For example, a thickness of electrode pads 26 is 10 μm to 20 μm.

Bumps 27 are formed on an upper surface of each electrode pad 26. For instance, bumps 27 are gold bumps. The height of the bumps 27 may range from 10 μm to 50 μm.

A gap 29 is formed between the packaging substrate 23 and the device chip 25.

The device chip 25 is mounted on the packaging substrate 23 using flip-chip bonding through the bumps 27, which electrically connect the device chip 25 to the multiple electrode pads 26.

The device chip 25 is a surface acoustic wave (SAW) device chip which includes a piezoelectric substrate made of a piezoelectric material. The piezoelectric 20 substrate may be composed of a single-crystal piezoelectric material such as lithium tantalate, lithium niobate, or quartz.

The thickness of the piezoelectric substrate can range from 100 μm to 300 μm. In another example, the piezoelectric substrate may be a piezoelectric ceramic substrate.

Alternatively, the device chip 25 may be a substrate formed by bonding a piezoelectric substrate to a supporting substrate. The supporting substrate may be made of sapphire, silicon, alumina, spinel, quartz, or glass. In this case, the thickness of the piezoelectric substrate can be between 0.3 μm and 5 μm.

An elastic wave element 52 is formed on the piezoelectric substrate. For example, a transmission filter or a receiving filter comprising multiple elastic wave elements 52 is formed on the main surface of the device chip 25.

In another example, a duplexer comprising a transmission filter and a receiving filter may be formed on the main surface of the device chip 25.

The transmission filter is designed to allow an electrical signals of a desired frequency band can pass through. For example, the transmitting filter includes a ladder-type filter including a plurality of series resonators and a plurality of parallel resonators.

The receiving filter is designed to allow an electrical signal of a desired frequency band can pass through. For example, the receiving filter includes a ladder-type filter including a plurality of series resonators and a plurality of parallel resonators.

The sealing portion 28 seals the device chip 25. For example, the sealing portion 28 may be made of an insulating material like synthetic resin. Alternatively, the sealing portion 28 may be metal.

When the sealing portion 28 is made of synthetic resin, the resin may be epoxy resin or polyimide. Preferably, the sealing portion 28 is formed using epoxy resin through a low-temperature curing process.

A gap 29 is formed in an area where the packaging substrate 23 and device chip 25 face each other. Anong the electrode pads 26 formed on the packaging substrate 23, the bump 27L2 that is bonded to a node pad NODE described later, along with the electrode pad to which it is bonded, constitutes the second inductor L2.

In other words, the second inductor L2 is the total series inductance from the node pad NODE to the ground electrode on the packaging substrate 23, including the parasitic inductance of the bumps.

Next, FIG. 2 illustrates an example of the elastic wave element 52 formed on the device chip 25. FIG. 2 is a schematic diagram of the elastic wave element (resonator) of the elastic wave device in Embodiment 1.

As shown in FIG. 2, an interdigital transducer (IDT) electrode 52a and a pair of reflectors 52b are formed on the main surface of the device chip 25. The IDT electrode 52a and the pair of reflectors 52b are configured to excite elastic waves (mainly SH waves).

For example, the IDT electrode 52a and the pair of reflectors 52b may be made of an aluminum-copper alloy. Alternatively, the IDT electrode 52a and the reflectors 52b can be made of metals or alloys such as aluminum, molybdenum, iridium, tungsten, cobalt, nickel, ruthenium, chromium, strontium, titanium, palladium, or silver.

The IDT electrode 52a and the pair of reflectors 52b may be formed as a multilayer metal film, with a thickness ranging from 150 nm to 450 nm.

The IDT electrode 52a has a pair of comb-like electrodes 52c arranged opposite each other. The comb-like electrodes 52c comprise multiple electrode fingers 52d and bus bars 52e.

Multiple electrode fingers 52d are arranged along the longitudinal axis. The bus bars 52e connect the multiple electrode fingers 52d.

One of the pair of reflectors 52b is adjacent to one side of the IDT electrode 52a, while the other reflector 52b is adjacent to the opposite side of the IDT electrode 52a.

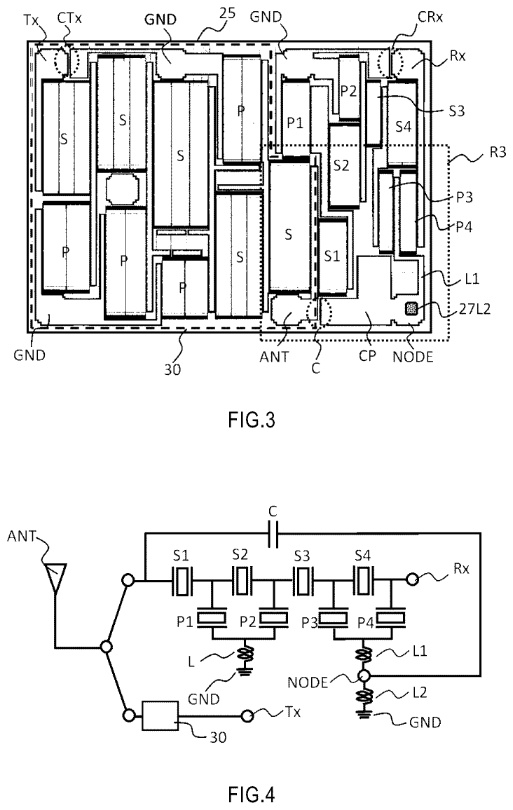

An example of a duplexer formed on the device chip 25 will be described with reference to FIG. 3. FIG. 3 shows a schematic view of the elastic wave device in Embodiment 1.

As shown in FIG. 3, a bandpass filter, specifically a transmission filter 30, is formed on the device chip 25. The transmission filter 30 is a ladder filter that includes a transmission pad Tx, an antenna pad ANT, a ground pad GND, multiple series resonators S, and multiple parallel resonators P.

Additionally, the transmission filter 30 includes a capacitor CTx formed between the ground pad GND and the transmission pad Tx. This reduces the parasitic capacitance between the transmission pad Tx and the antenna pad ANT, as well as between the transmission pad Tx and the reception pad Rx, improving the attenuation characteristics and isolation of the transmission filter.

As shown in FIG. 3, a bandpass filter, specifically a receiving filter, is also formed on the device chip 25. The receiving filter is a ladder filter comprising a reception pad Rx, the antenna pad ANT, the ground pad GND, multiple series resonators S1-S4, and multiple parallel resonators P1-P4.

Furthermore, the receiving filter includes a first inductor L1, a node pad NODE, capacitor wiring CP, and a capacitor C. The receiving filter also includes a capacitor CRx formed between the ground pad GND and the reception pad Rx. This reduces the parasitic capacitance between the reception pad Rx and the antenna pad ANT, as well as between the reception pad Rx and the transmission pad Tx, enhancing the attenuation characteristics and isolation of the receiving filter.

Additionally, a bump 27L2, which constitutes part of a second inductor L2, is formed on the node pad NODE. The second inductor L2 includes a parasitic inductance portion of the bump 27L2 formed on the node pad NODE.

The capacitor C, shown as the area within the dashed lines, is composed of the parasitic capacitance between the sidewall portion of the antenna wiring electrically connected to the antenna pad ANT and the sidewall portion of the capacitor wiring CP electrically connected to the node pad NODE. This configuration reduces the parasitic capacitance between the antenna pad ANT and the reception pad Rx, as well as between the antenna pad ANT and the transmission pad Tx, improving the attenuation characteristics of both the receiving filter and the transmission filter while forming a circuit between the node pad NODE and the antenna pad ANT.

In capacitor C, the average distance between the wiring sidewall portion of the antenna pad ANT and the sidewall portion of the capacitor wiring CP is 2 μm. The wiring thicknesses of the antenna pad ANT and the capacitor wiring CP are each, for example, 200 nm.

As shown in FIG. 3, the capacitor wiring CP is electrically and physically connected only to the node pad NODE. Additionally, the area of the capacitor wiring CP can be larger than the combined areas of the antenna pad ANT and the node pad NODE. This configuration reduces the wiring resistance of the capacitor wiring CP. In some embodiments, the width of the capacitor wiring CP is greater than the width of the antenna wiring.

Furthermore, the antenna pad ANT, receiving pad Rx, and node pad NODE are arranged to form a right-angled triangle when their positions are considered as vertices. The node pad NODE is located at the right-angle vertex. This arrangement optimizes the transmission and reception isolation of the duplexer, shortens the distance between the antenna pad ANT and the node pad NODE, and further reduces the wiring resistance of the capacitor wiring CP.

FIG. 4 shows the schematic circuit diagram of the elastic wave device in Embodiment 1. From the perspective of the antenna pad ANT, the third parallel resonator P3 and the fourth parallel resonator P4 are connected in parallel to the first inductor L1. In some embodiments, the inductance value of the second inductor L2 is at least twice the inductance value of the first inductor L1.

For example, the inductance value of the first inductor L1 can be 0.05 nH. The first inductor L1 is connected to the node pad NODE. The first inductor L1 and the second inductor L2 are connected through the node pad NODE.

For example, the inductance value of the second inductor L2 can be 0.1 nH, and the second inductor L2 is connected to the grounded pad GND. The capacitor C is connected between the node pad NODE and the antenna pad ANT through the capacitor wiring CP. The capacitance value of capacitor C can be 0.03 pF. Parts of the transmission filter 30 are not described in detail.

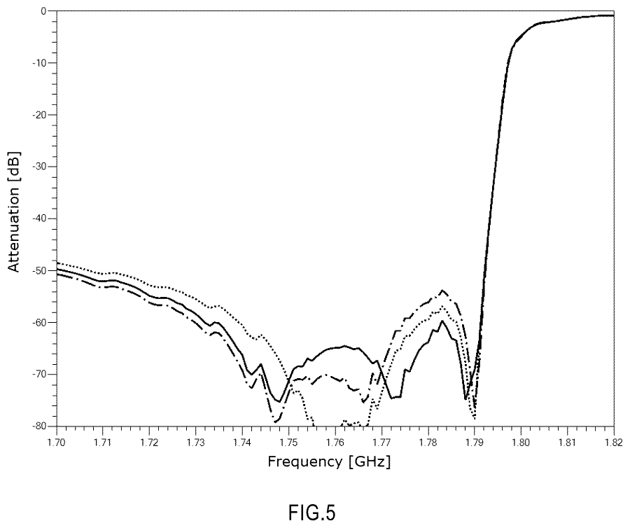

FIG. 5 shows the attenuation characteristics on the low-frequency side of the passband of the receiving filter of the elastic wave device 20 in Embodiment 1. The attenuation characteristics of the receiving filter of the elastic wave device 20 on the low-frequency side of the passband are shown as a solid line. Additionally, the attenuation characteristics of Comparative Example 1 are represented by a dashed line, and those of Comparative Example 2 by a dot-dash line.

Comparative Example 1 is a structure without the capacitor C present in Embodiment 1. Comparative Example 2 is a structure without the capacitor C present Embodiment 1, with the inductance value of the second inductor L2 set to 0.2 nH. The other structures are the same as in Embodiment 1.

As shown in FIG. 5, the attenuation characteristics of Comparative Example 2 on the low-frequency side of the passband are improved over those of Comparative Example 1 on the low-frequency side of the attenuation frequency range. However, the attenuation characteristics on the high-frequency side of the low-frequency attenuation frequency range deteriorate.

In this case, Embodiment 1 performs comparably to Comparative Example 2 on the low-frequency side of the low-frequency attenuation frequency range, outperforming Comparative Example 1. Furthermore, on the high-frequency side of the low-frequency attenuation frequency range, the attenuation characteristics are also superior to Comparative Example 1.

Although there is some deterioration in the attenuation characteristics in the intermediate frequency range between the low-frequency and high-frequency sides of the low-frequency attenuation range, an overall balance of the attenuation characteristics across the entire low-frequency attenuation range is better achieved.

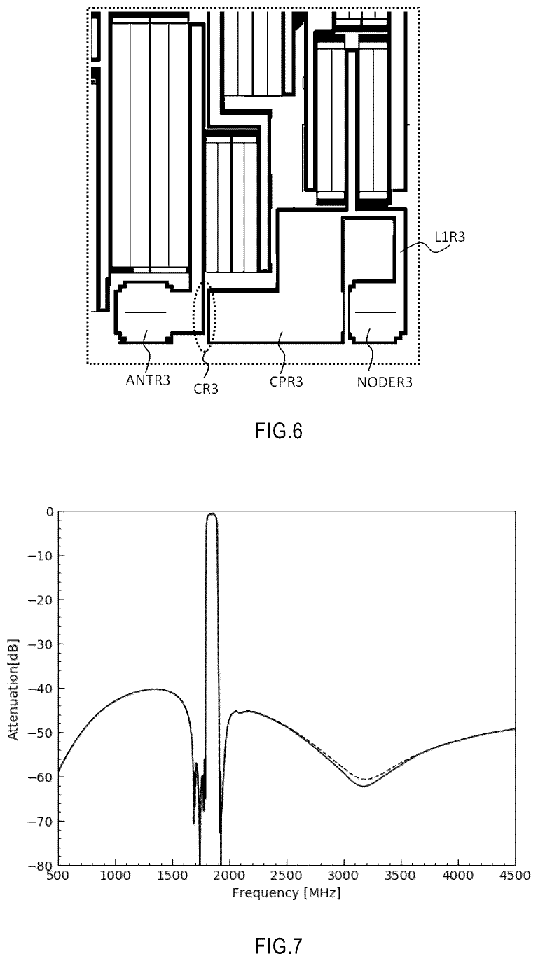

FIG. 6 shows the structure of Comparative Example 3, displaying the region corresponding to the area R3 outlined by dashed lines in FIG. 3. In Comparative Example 3, the inductor L1R3, corresponding to the first inductor L1 in Embodiment 1, is electrically connected to the capacitor wiring CPR3, which corresponds to the capacitor wiring CP in Embodiment 1.

Moreover, the capacitor wiring CPR3 is connected to the parallel resonator. The capacitor CR3 in Comparative Example 3 is optimized within this structure, with a capacitance value of 0.015 pF. Other structures are the same as in Embodiment 1.

FIG. 7 is a characteristic graph comparing the receiving filter of the elastic wave device in Embodiment 1 and the receiving filter in Comparative Example 3. The solid line represents the characteristics of the receiving filter in Embodiment 1, while the dashed line represents those in Comparative Example 3.

As shown in FIG. 7, the pole of the receiving filter in Embodiment 1 is deeper on the high-frequency side of the passband. By placing the pole at significant frequencies, such as the second harmonic, Embodiment 1 achieves superior characteristics compared to Comparative Example 3.

In conclusion, according to Embodiment 1, an elastic wave device can be provided that improves attenuation characteristics on both the low-frequency and high-frequency sides of the passband.

### Embodiment 2

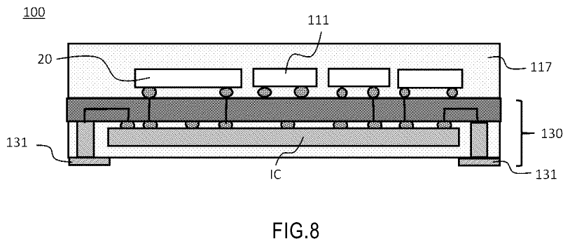

FIG. 8 is a longitudinal sectional view of a module incorporating the elastic wave device from Embodiment 1. Identical or corresponding parts from Embodiment 1 are labeled with the same symbols, and descriptions of corresponding parts are omitted.

As shown in FIG. 8, the module 100 includes a wiring substrate 130, multiple external connection terminals 131, an integrated circuit component IC, an elastic wave device 20, an inductor 111, and a sealing portion 117.

Multiple external connection terminals 131 are formed on the lower surface of the wiring substrate 130. These external connection terminals 131 are pre-installed on the mainboard of a mobile terminal.

For example, the integrated circuit component IC is mounted inside the wiring substrate 130. The integrated circuit component IC includes a switch circuit and a low-noise amplifier.

The elastic wave device 20 is mounted on the main surface of the wiring substrate 130.

The inductor 111 is also mounted on the main surface of the wiring substrate 130, serving for impedance matching. For instance, the inductor 111 is an Integrated Passive Device (IPD).

The sealing portion 117 encloses multiple electronic components, including the elastic wave device 20.

In summary, according to Embodiment 2, the module 100 includes the elastic wave device 20. Therefore, an elastic wave device module with enhanced electrical durability can be provided.

Although several aspects of at least one embodiment have been described, it should be understood that various modifications, adjustments, and improvements are apparent to those skilled in the art. Such modifications, adjustments, and improvements are intended to be part of this disclosure and fall within the scope of this disclosure.

It should be understood that the embodiments of the methods and devices described here are not limited to the structural and layout details of the components described in the above description or shown in the drawings. The methods and devices can be implemented in other embodiments and executed or performed in various ways.

The specific embodiments provided are merely exemplary and are not intended to limit the scope.

The terminology and expressions used in this disclosure are for descriptive purposes and not intended to limit. Here, the use of “including,” “having,” “with,” “comprising,” and variations thereof means inclusion of the listed items and their equivalents, as well as additional items.

References to “or” may indicate any of the terms, meaning one, more than one, or all of the terms mentioned.

References to front, rear, left, right, top, bottom, up, down, lateral, longitudinal, front side, and back side are intended to facilitate description. These references do not imply that the components of this disclosure are limited to a particular location or spatial orientation. Thus, the above descriptions and drawings are merely illustrative.

What is claimed is:

1. An elastic wave device, comprising:
a packaging substrate with a ground electrode;
a piezoelectric substrate mounted on said packaging substrate;
multiple series resonators and multiple parallel resonators formed on said piezoelectric substrate, which constitute a bandpass filter;
an antenna pad and a node pad formed on said piezoelectric substrate;
a first inductor formed on said piezoelectric substrate and connected to a first parallel resonator which is one of said multiple parallel resonators;
a second inductor connected between said node pad and said ground electrode;
a capacitor formed on said piezoelectric substrate and connected in parallel between said first inductor and said second inductor;
Wherein said capacitor is directly connected to the antenna pad.

2. The elastic wave device according to claim 1, wherein said capacitor is formed by a sidewall portion of the antenna wiring electrically connected to said antenna pad and a sidewall portion of said capacitor wiring electrically connected to the node pad.

3. The elastic wave device according to claim 2, wherein an area of said capacitor wiring is greater than a combined area of said antenna pad and said node pad.

4. The elastic wave device according to claim 2, wherein a width of said capacitor wiring is greater than a width of said antenna wiring.

5. The elastic wave device according to claim 2, wherein the capacitor wiring is physically connected only to the node pad.

6. The elastic wave device according to claim 1, wherein an inductance value of said second inductor is at least twice an inductance value of said first inductor.

7. The elastic wave device according to claim 1, wherein a second parallel resonator among said multiple parallel resonators is connected to said first inductor.

8. The elastic wave device according to claim 1, further comprising a reception pad formed on said piezoelectric substrate, and said bandpass filter is a receiving filter, wherein said antenna pad, said node pad, and said reception pad are positioned such that their vertices form a right triangle, with said node pad located at the right-angle vertex.

9. The elastic wave device according to claim 1, further comprising a transmission filter formed on the piezoelectric substrate, and the bandpass filter is a receiving filter.

10. The elastic wave device according to claim 1, further comprising a reception pad, a ground pad and a second capacitor formed on said piezoelectric substrate, wherein said second capacitor is formed between said ground pad and said reception pad.

11. The elastic wave device according to claim 1, further comprising a transmission filter that includes a transmission pad, an antenna pad, a ground pad, multiple series resonators, and multiple parallel resonators.

12. The elastic wave device according to claim 11, wherein said transmission filter further includes a capacitor formed between said ground pad and said transmission pad.

13. The elastic wave device according to claim 1, wherein said second inductor is a total series inductance from said node pad to said ground electrode on the packaging substrate.

14. The elastic wave device according to claim 1, further comprising a bump which constitutes part of said second inductor and is formed on the node pad.

15. The elastic wave device according to claim 14, wherein the second inductor includes a parasitic inductance portion of the bump formed on the node pad.

16. A module, including an elastic wave device according to claims 1.

17. The Module according to claim 14, wherein said capacitor is formed by a sidewall portion of the antenna wiring electrically connected to the antenna pad and a sidewall portion of said capacitor wiring electrically connected to the node pad.

18. The Module according to claim 14, wherein an area of said capacitor wiring is greater than a combined area of said antenna pad and said node pad.

19. The Module according to claim 14, wherein a width of said capacitor wiring is greater than a width of said antenna wiring.

20. The Module according to claim 14, wherein a width of said capacitor wiring is greater than a width of said antenna wiring.
